(19) United States
(12) Patent Application Publication
(10) Pub. No.: US 2013/0161647 A1
(43) Pub. Date: Jun. 27, 2013

(54) INGOT, SUBSTRATE, AND SUBSTRATE GROUP

(71) Applicant: SUMITOMO ELECTRIC INDUSTRIES, LTD., Osaka (JP)

(72) Inventors: Shinsuke FUJIWARA, Itami-shi (JP); Shin HARADA, Osaka (JP); Taro NISHIGUCHI, Itami-shi (JP)

(73) Assignee: SUMITOMO ELECTRIC INDUSTRIES, LTD., Osaka (JP)

(21) Appl. No.: 13/681,564

(22) Filed: Nov. 20, 2012

Related U.S. Application Data
(60) Provisional application No. 61/580,270, filed on Dec. 26, 2011.

(30) Foreign Application Priority Data
Dec. 26, 2011 (JP) 2011-282799

(51) Int. Cl. H01L 29/24; H01L 29/02

(52) U.S. Cl. CPC H01L 29/24; H01L 29/02
USPC 257/77; 257/655

(57) ABSTRACT

An ingot, a substrate, and a substrate group are obtained each of which is made of silicon carbide and is capable of suppressing variation of characteristics of semiconductor devices. The ingot is made of single-crystal silicon carbide, and has p type impurity. The ingot has a thickness of 10 mm or greater in a growth direction thereof. Further, the ingot has an average carrier density of 1×10¹⁶ cm⁻³or greater. Further, the ingot has a carrier density fluctuating in the growth direction by ±80% or smaller relative to the average carrier density. In this way, variation of carrier density among substrates obtained from the ingot is suppressed, thereby suppressing variation of characteristics of semiconductor devices manufactured using the substrates.

### BACKGROUND OF THE INVENTION

1. Field of the Invention

The present invention relates to an ingot, a substrate, and a substrate group, more particularly, an ingot, a substrate, and a substrate group each of which is made of silicon carbide and is capable of suppressing variation of characteristics of semiconductor devices.

2. Description of the Background Art

In recent years, in order to achieve high breakdown voltage, low loss, and utilization of semiconductor devices under a high temperature environment, silicon carbide has adopted as a material for a semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high breakdown voltage, reduced on-resistance, and the like. Further, the semiconductor device thus adopting silicon carbide as its material has characteristics less deteriorated even under a high temperature environment than those of a semiconductor device adopting silicon as its material, advantageously.

Such a semiconductor device adopting silicon carbide as its material is manufactured by forming an epitaxial growth layer, an oxide film, an electrode, and the like on a substrate made of silicon carbide. Further, a predetermined amount of impurity is introduced into the substrate for the semiconductor device in order to adjust conductivity type and carrier (hole and electron) density of the substrate as desired. Specifically, for example, a mixture of a SiC (silicon carbide) source material and an impurity source material such as Al (aluminum) is heated and sublimated to cause crystal growth on a seed substrate, thereby manufacturing an ingot having an impurity introduced therein. By slicing the ingot, the substrate is obtained.

In manufacturing the ingot made of silicon carbide, most of the impurity source material is consumed and exhausted at an initial stage of the crystal growth due to high crystal growth temperature of silicon carbide, with the result that the impurity concentration becomes lower as the crystal growth advances, disadvantageously. To address this, for example, Japanese Patent Laying-Open No. 63-85097 (Patent Literature 1) proposes a method for uniformizing an impurity concentration by pre-heating and crystallizing a mixture of a SiC source material and an impurity source material such as Al so as to suppress the exhaustion of Al during the crystal growth.

However, as a result of inspection by the present inventors, variation of characteristics takes place even in semiconductor devices manufactured using substrates obtained from the ingot adapted to have the uniformized impurity concentration such as the one manufactured using the method proposed in Patent Literature 1, disadvantageously.

### SUMMARY OF THE INVENTION

The present invention has been made in view of the foregoing problem and has its object to provide an ingot, a substrate, and a substrate group, each of which is capable of suppressing variation of characteristics of semiconductor devices.

An ingot of the present invention is an ingot made of single-crystal silicon carbide and containing a p type impurity. The ingot has a thickness of 10 mm or greater in a growth direction thereof. The ingot has an average carrier density of 1×10¹⁶ cm⁻³ or greater. The ingot has a carrier density fluctuating in the growth direction by ±80% or smaller relative to the average carrier density.

Here, the state in which the carrier density fluctuates by ±80% or smaller relative to the average carrier density is intended to indicate a state in which the maximum value of the carrier density is 180% or smaller relative to the average carrier density and the minimum value of the carrier density is 20% or greater relative to the average carrier density. Further, the fluctuation of carrier density in the growth direction of the ingot can be confirmed by measuring carrier densities in a plurality of arbitrary points in the growth direction of the ingot. Further, the carrier density refers to a difference between hole density and electron density, but in the ingot mainly containing the p type impurity, it can be regarded that the carrier density and the hole density are substantially equal to each other.

The present inventors have conducted detailed study on a cause of variation of characteristics of semiconductor devices employing substrates obtained from a conventional ingot. As a result, it has been found that in the conventional ingot, as the thickness thereof becomes large to reach or exceed 10 mm, variation of carrier density in the growth direction becomes large to result in variation of characteristics of the semiconductor devices manufactured using the substrates obtained from the ingot. Accordingly, the present inventors have arrived at the present invention.

The ingot in the present invention has a thickness of 10 mm or greater in the growth direction and achieves suppression of variation of carrier density in the growth direction. Accordingly, variation of carrier density among the substrates obtained from the ingot thus having a thickness of 10 mm or greater is suppressed, thereby suppressing variation of characteristics of semiconductor devices manufactured using the substrates. Thus, according to the ingot of the present invention, there can be provided an ingot capable of suppressing variation of characteristics of semiconductor devices.

The ingot may contain aluminum as the p type impurity. Aluminum is suitable as the p type impurity for silicon carbide, but has a vapor pressure highly different from that of silicon carbide. Accordingly, variation of carrier density is likely to take place in the growth direction of the ingot. Hence, when aluminum is contained as the p type impurity, there can be suitably employed the ingot of the present invention in which the variation of carrier density in the growth direction can be suppressed.

The ingot may be formed through a sublimation method. Accordingly, the ingot can be more readily formed while suppressing the variation of carrier density in the growth direction.

In the ingot, the carrier density may monotonously fluctuate in the growth direction. In this way, the carrier density of a substrate obtained from the ingot can be readily known.

In the ingot, the carrier density may fluctuate in the growth direction by ±50% or smaller relative to the average carrier density. Accordingly, there can be provided an ingot capable of more effectively suppressing variation of characteristics of semiconductor devices.

In the ingot, the carrier density may fluctuate in the growth direction by ±20% or smaller relative to the average carrier density. Accordingly, there can be provided an ingot capable of further effectively suppressing variation of characteristics of semiconductor devices.

A substrate of the present invention is a substrate obtained from the above-described ingot of the present invention. Thus, according to the substrate of the present invention, there can be provided a substrate capable of suppressing variation of characteristics of semiconductor devices.

In the substrate, the carrier density may fluctuate in a main surface thereof by ±20% or smaller relative to the average carrier density. Accordingly, semiconductor devices in which variation of characteristics is suppressed can be more readily manufactured.

Further, the fluctuation of carrier density in the main surface of the substrate can be confirmed by measuring carrier densities in a plurality of arbitrary points in the main surface thereof.

In the substrate, a main surface thereof may have an area of 100 cm² or greater. In this way, semiconductor devices can be manufactured more efficiently.

The substrate may have a warpage of 20 μm or smaller. In this way, semiconductor devices of higher quality can be manufactured.

A substrate group of the present invention is a substrate group obtained from one ingot. The substrate group has an average carrier density of 1×10¹⁶ cm⁻³ or greater. Variation of carrier density among substrates forming the substrate group is ±80% or smaller relative to the average carrier density of the substrate group.

Here, the average carrier density of the substrate group refers to an average of carrier densities of all the substrates forming the substrate group.

In the substrate group of the present invention, the variation of carrier density among the substrates forming the substrate group is suppressed, thereby suppressing variation of characteristics of semiconductor devices manufactured using the substrates. Thus, according to the substrate group of the present invention, there can be provided an substrate group capable of suppressing variation of characteristics of semiconductor devices.

As apparent from the description above, according to the ingot, the substrate, and the substrate group of the present invention, there can be provided an ingot, a substrate, and a substrate group, each of which is capable of suppressing variation of characteristics of semiconductor devices. The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view showing an ingot.

FIG. 2 is a schematic view showing a substrate group.

FIG. 3 is a schematic view showing a substrate.

FIG. 4 is a flowchart schematically showing methods for manufacturing the ingot and the substrate.

FIG. 5 is a schematic view for illustrating the method for manufacturing the ingot.

FIG. 6 is a schematic view for illustrating the method for manufacturing the substrate.

### DESCRIPTION OF THE PREFERRED EMBODIMENTS

The following describes an embodiment of the present invention with reference to figures. It should be noted that in the below-mentioned figures, the same or corresponding portions are given the same reference characters and are not described repeatedly. Further, in the present specification, an individual orientation is represented by [], a group orientation is represented by <>, and an individual plane is represented by () and a group plane is represented by {}. In addition, a negative index is supposed to be crystallographically indicated by putting “-” (bar) above a numeral, but is indicated by putting the negative sign before the numeral in the present specification.

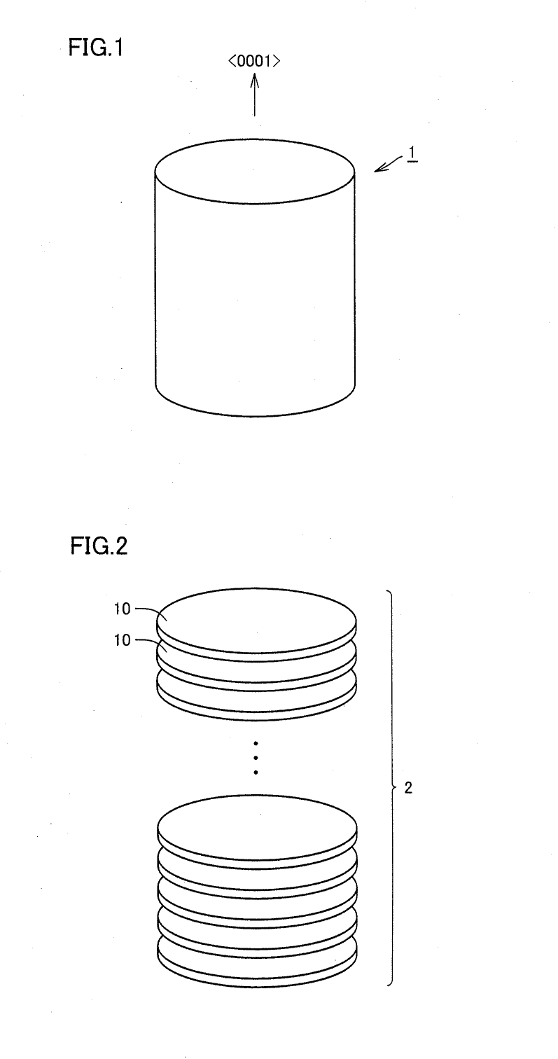

First, the following describes an ingot according to one embodiment of the present invention. Referring to FIG. 1, an ingot 1 according to the present embodiment is made of single-crystal silicon carbide of 4 H type and formed by growing it in a <0001> direction as indicated by an arrow by means of a sublimation method, for example. Silicon carbide can be readily grown in the <0001> direction. Hence, by setting the growth direction to the <0001> direction as described above, ingot 1 can be formed readily. Further, ingot 1 has a thickness of 10 mm or greater in the <000122 direction.

Ingot 1 contains a p type impurity suitable as a p type impurity for silicon carbide, such as Al (aluminum) or B (boron). Hence, ingot 1 has p type conductivity. Further, ingot 1 has an average carrier density of 1×10¹⁶cm³ or greater. The carrier density fluctuates in the growth direction, i.e., the <0001> direction by ±80% or smaller relative to the average carrier density.

Thus, ingot 1 according to the present embodiment has a thickness of 10 mm or greater in the <0001> direction and achieves suppression of variation of carrier density in the <0001> direction. Accordingly, variation of carrier density among substrates obtained from ingot 1 thus having a thickness of 10 mm or greater is suppressed, thereby suppressing variation of characteristics of semiconductor devices manufactured using the substrates. Thus, ingot 1 according to the present embodiment is an ingot capable of suppressing variation of characteristics of semiconductor devices.

Further, by forming ingot 1 using the sublimation method as described above, ingot 1 can be more readily formed while suppressing the variation of carrier density in the <0001> direction.

Further, as described above, Al contained in ingot 1 is suitable as the p type impurity for silicon carbide, but has a vapor pressure highly different from that of silicon carbide. Accordingly, variation of carrier density is likely to take place in the growth direction of ingot 1. Hence, when aluminum is contained as the p type impurity, ingot 1 according to the present embodiment can be suitably employed in which the variation of carrier density in the growth direction can be suppressed.

Further, in ingot 1, the carrier density may monotonously fluctuate in the <0001> direction.

Further, the carrier density of ingot 1 may fluctuate in the <0001> direction by ±50% or smaller, more preferably, ±20% or smaller relative to the average carrier density. Accordingly, variation of characteristics of semiconductor devices can be suppressed more effectively.

The following describes a substrate group and a substrate according to the present embodiment. Referring to FIG. 2, a substrate group 2 according to the present embodiment is a substrate group obtained from one ingot 1, and is formed of a plurality of substrates 10. Substrate group 2 includes, for example, all the substrates 10 obtained from ingot 1.

Substrate group 2 has an average carrier density of 1×10¹⁶ cm ⁻³ or greater. Further, variation of carrier density among substrates 10 forming substrate group 2 is ±80% or smaller, preferably ±50% or smaller, more preferably ±20% or smaller relative to the average carrier density of substrate group 2.

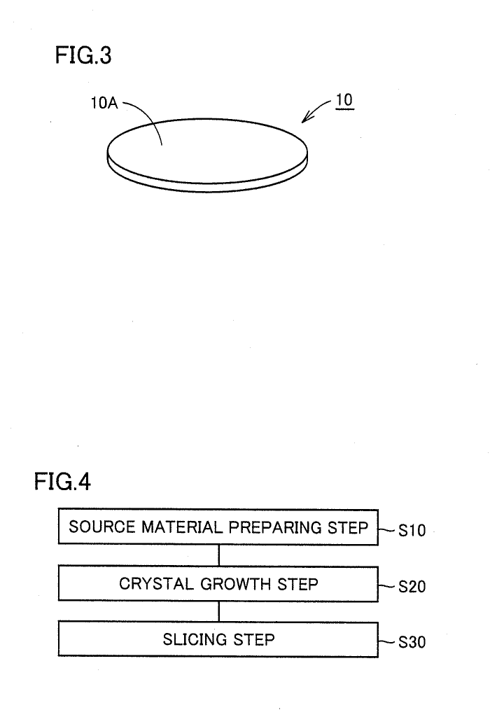

Referring to FIG. 3, each of substrates 10 is a substrate according to the present embodiment, and is obtained from ingot 1 according to the present embodiment. A plane forming main surface 10A of substrate 10 has an off angle of 8° or smaller relative to the {0001} plane, and may have an off angle of 4° or smaller relative to the {0001} plane.

Further, main surface 10A of substrate 10 has an area of 100 cm² or greater. Use of substrate 10 having main surface 10A having such a large area leads to more efficient manufacturing of semiconductor devices.

Further, distribution of carrier density in main surface 10A of substrate 10 is ±20% or smaller relative to the average carrier density of substrate 10. By using substrate 10 in which the variation of carrier density is thus suppressed in main surface 10A, there can be more readily manufactured semiconductor devices in which variation of characteristics is suppressed.

Further, substrate 10 has a warpage of 20 μm or smaller. Use of substrate 10 having the warpage thus suppressed leads to manufacturing of semiconductor devices of higher quality.

Thus, in substrate group 2 according to the present embodiment, the variation of carrier density among substrates 10 forming substrate group 2 is suppressed, thereby suppressing variation of characteristics of semiconductor devices manufactured using substrates 10. Thus, substrate group 2 and substrate 10 according to the present embodiment are a substrate group and a substrate both capable of suppressing variation of characteristics of semiconductor devices.

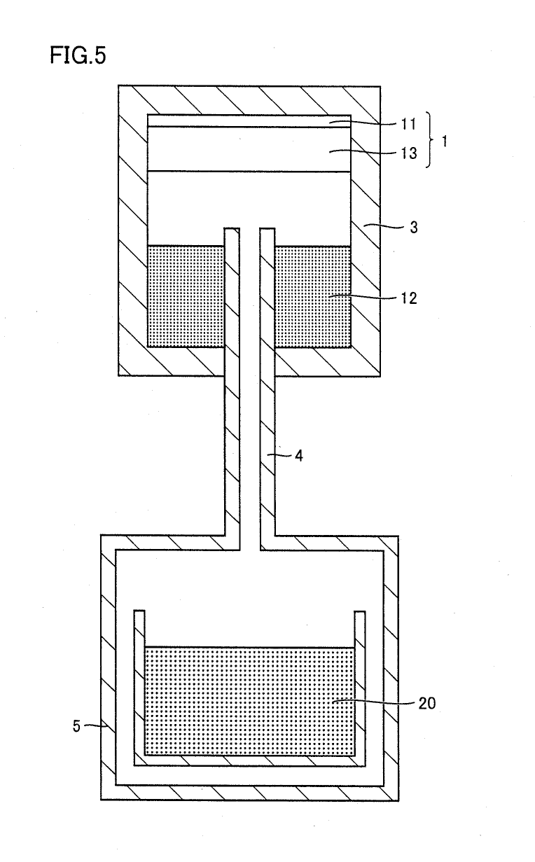

The following describes methods for manufacturing the ingot and the substrate according to the present embodiment with reference to FIG. 4 to FIG. 6. First described is the method for manufacturing the ingot according to the present embodiment. In the method for manufacturing the ingot according to the present embodiment, ingot 1 according to the present embodiment can be manufactured. Referring to FIG. 4, first, as a step (S10), a source material preparing step is performed. In this step (S10), referring to FIG. 5, a seed substrate 11 made of single-crystal silicon carbide, and SiC powders 12 serving as a silicon carbide source are disposed in a crucible 3 made of purified graphite. Further, an Al/B mixture 20 obtained by mixing Al and B with each other at a predetermined ratio is disposed in a crucible 6 made of TaC (tantalum carbide) and provided in a reservoir 5 connected to crucible 3 via a connecting pipe 4.

Next, as a step (S20), a crystal growth step is performed. In this step (S20), SiC powders 12 and Al/B mixture 20 are heated and sublimated to grow a SiC single crystal 13 on seed substrate 11, thereby forming ingot 1 containing Al as the p type impurity. Specifically, referring to FIG. 5, crucible 3 and reservoir 5 are first heated to predetermined temperatures while being evacuated. Then, for example, an inert gas such as Ar (argon) is introduced to achieve a desired pressure, and heating is further performed to a crystal growth temperature. On this occasion, Al/B mixture 20 is melted to obtain Al/B mixture melt 20. Then, after it is left for a predetermined time, pressure in each of crucible 3 and reservoir 5 is reduced to a desired pressure. Crystal growth is started. In this way, ingot 1 having a desired thickness is obtained.

Further, in this step (S20), it is preferable to set the heating temperature of Al/B mixture 20 to be higher than that of SiC powder 12. Accordingly, SiC powders 12 heated and sublimated can be suppressed from being introduced and deposited in reservoir 5. By performing steps (S10) and (S20), ingot 1 is manufactured, thus completing the method for manufacturing the ingot according to the present embodiment.

Thus, in the method for manufacturing the ingot according to the present embodiment, in step (S20), Al/B mixture 20 is heated and sublimated together with SiC powders 12 to advance the crystal growth on seed substrate 11. When SiC powders 12 and Al are heated and sublimated together as in the method for manufacturing the conventional ingot, Al is exhausted at the initial stage of crystal growth due to the difference in vapor pressure between silicon carbide and Al. As a result, distribution of carrier density becomes non-uniform in the growth direction of the ingot. In contrast, in the method for manufacturing the ingot according to the present embodiment, B is added to reduce the vapor pressure of Al, and SiC powders 12 and the Al/B mixture are heated at different, appropriate temperatures, thereby advancing the crystal growth while suppressing exhaustion of Al. Therefore, according to the method for manufacturing the ingot according to the present embodiment, ingot 1 having uniform distribution of carrier density in the growth direction can be manufactured. It should be noted that the vapor pressure of B is smaller than that of Al by several digits, so that ingot 1 contains B at a concentration smaller than that of Al.

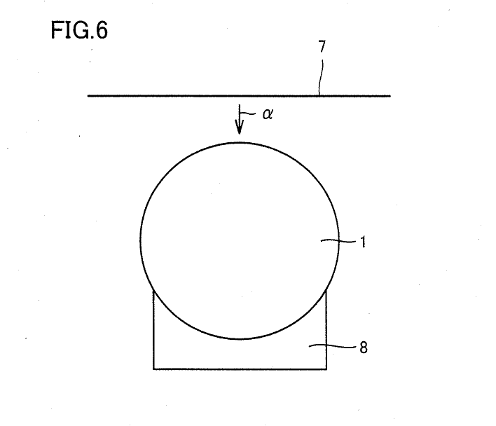

The following describes the method for manufacturing the substrate according to the present embodiment. In the method for manufacturing the substrate according to the present embodiment, substrate group 2 and substrate 10 according to the present embodiment can be manufactured. Referring to FIG. 4, in the method for manufacturing the substrate according to the present embodiment, a slicing step is performed as a step (S30). In this step (S30), referring to FIG. 6, ingot 1 is first placed on a holder 8 with a portion of its side surface being supported by holder 8. Next, a wire 7 is moved to travel in a direction along the diameter direction of ingot 1 and approaches ingot 1 with wire 7 itself being along a cutting direction α perpendicular to the travel direction so as to bring wire 7 into contact with ingot 1. Then, by continuously advancing wire 7 with wire 7 itself being along cutting direction α, ingot 1 is cut. In this way, substrate 10 (see FIG. 3) obtained from ingot 1 and substrate group 2 (see FIG. 2) formed of the plurality of substrates 10 are manufactured.

Now, the cutting of ingot 1 is described more in detail as follows. For example, wire 7, which is made of an alloy containing iron and nickel, is moved in contact with ingot 1 while supplying a cutting fluid to the region where wire 7 and ingot 1 are in contact with each other. An exemplary cutting fluid is slurry containing single-crystal diamond as loose abrasives and a cutting fluid. In this way, ingot 1 is cut. With ingot 1 being thus sliced, substrate group 2 and substrate 10 are obtained as shown in FIG. 2 and FIG. 3.

### Example

An experiment was conducted to examine distribution of carrier density in the growth direction of an ingot manufactured using the method for manufacturing the ingot according to the present embodiment, as well as distribution of carrier density in a surface of a substrate obtained from the ingot. As the methods for manufacturing the ingot and the substrate, the respective methods for manufacturing the ingot and the substrate according to the present embodiment were used. Specifically, first, seed substrates, SiC powders, and Al/B mixtures were prepared. Each of the seed substrates was made of 4 H—SiC, had a main surface having an off angle of 4° relative to the (0001) plane, and had a diameter of 6 inches. The SiC powders (4 kg) were made of 4 H—SiC and had 6 N purity (purity: 99.9999%). Each of the Al/B mixtures was obtained by mixing Al of 6N purity and B of 2N purity (purity: 99.0%) at a predetermined ratio. As the Al/B mixtures, there were prepared Al/B mixtures in which ratios of the mass of Al to the mass of B were respectively 0.1 mass %, 0.3 mass %, 1.0 mass %, 3.0 mass %, and 5.0 mass %. Further, B (boron) was heated in an Ar (argon) atmosphere at 2400° C. under 100 Pa for the purpose of purification before being mixed with Al. About the half of B in amount was sublimated and B remaining was used. Next, each of the seed substrates and each of the SiC powders were disposed in a crucible made of purified graphite and each of the Al/B mixtures was disposed in a crucible made of TaC and provided in a reservoir connected to the foregoing crucible via a connecting pipe. Next, while evacuating the crucible and the reservoir, heating was performed to 1500° C. While supplying Ar gas at a flow rate of 1 s (standard) 1/min until pressure in each of the crucible and the reservoir reaches 90 kPa, heating was performed such that the seed crystal had a temperature of 2250° C., the SiC source material had a temperature of 2290° C., and the reservoir had a temperature of 2300° C. Then, the Al/B mixture in the reservoir was left for 5 hours to mix them uniformly. Thereafter, the pressure in the crucible was reduced to 1 kPa. Crystal growth was started. The crystal was grown for 100 hours, thereby obtaining an ingot made of 4 H—SiC and having a thickness of about 30 mm in the growth direction. Next, the ingot was sliced substantially perpendicularly to the growth direction at a pitch of 1 mm. Then, both the surfaces of each obtained substrate were mirror-polished, thereby obtaining substrates each having a thickness of 650±10 μm. Then, hall measurement was performed in the central region of each of the substrates so as to examine distribution of carrier density in the growth direction of the ingot. Further, by performing hall measurement in a plurality of locations in a main surface of the substrate, distribution of carrier density in the surface of the substrate was also examined. Table 1 shows the distribution of carrier density in the growth direction. Meanwhile, Table 2 shows the distribution of carrier density in the surface of the substrate.

TABLE 1

| | Al/B (mass %) | | | | | |
|---|---|---|---|---|---|---|
| Substrate | 0.1 | 0.3 | 0.5 | 1 | 3 | 5 |
| No. | Hole Density (cm⁻²) | | | | | |
| 1 | 1.2 × 10¹⁶ | 3.5 × 10¹⁶ | 5.8 × 10¹⁶ | 1.1 × 10¹⁷ | 3.4 × 10¹⁷ | 5.6 × 10¹⁷ |
| 10 | 1.1 × 10¹⁶ | 3.4 × 10¹⁶ | 5.6 × 10¹⁶ | 1.0 × 10¹⁷ | 3.2 × 10¹⁷ | 5.4 × 10¹⁷ |
| 20 | 1.1 × 10¹⁶ | 3.3 × 10¹⁶ | 5.4 × 10¹⁶ | 9.0 × 10¹⁶ | 3.0 × 10¹⁷ | 5.2 × 10¹⁶ |
| 30 | 1.0 × 10¹⁶ | 3.1 × 10¹⁶ | 5.2 × 10¹⁶ | 9.0 × 10¹⁶ | 2.8 × 10¹⁷ | 5.0 × 10¹⁶ |

TABLE 2

Hole Density (cm⁻²)

| Substrate | | Maximum | Minimum | |
|---|---|---|---|---|
| No. | Average | Value | Value | Variance |
| 1 | 5.4 × 10¹⁷ | 5.5 × 10¹⁷ | 5.0 × 10¹⁷ | 1.5 × 10¹⁶ |
| 10 | 5.2 × 10¹⁷ | 5.3 × 10¹⁷ | 4.9 × 10¹⁷ | 1.2 × 10¹⁶ |
| 20 | 5.0 × 10¹⁷ | 5.2 × 10¹⁷ | 4.7 × 10¹⁷ | 1.4 × 10¹⁶ |
| 30 | 4.8 × 10¹⁷ | 4.9 × 10¹⁷ | 4.5 × 10¹⁷ | 1.1 × 10¹⁶ |

The following describes results of the experiment. As apparent from Table 1, the carrier density of each substrate was increased in proportion to the ratio of Al in the Al/B mixture. Meanwhile, variation of carrier density among the substrates was good, specifically, approximately 10% to approximately 20%. As apparent from Table 2, variance of carrier density in the surface of each substrate was also good, specifically, approximately ±10% or smaller. From these, it was confirmed that the distribution of carrier density was good in the growth direction of the ingot manufactured using the method for manufacturing the ingot according to the present embodiment and the distribution of carrier density was good in the surface of each of the substrates obtained from the ingot.

<Appendices>

Illustrations below include the following features.

(Appendix 1)

A method for manufacturing an ingot including the steps of:

preparing a seed substrate made of single-crystal silicon carbide, a silicon carbide source, and a mixture containing Al and B; and

causing crystal growth on the seed substrate by heating and sublimating the silicon carbide source and the mixture.

In the step of causing the crystal growth in the method for manufacturing the ingot, the mixture is heated and sublimated together with the silicon carbide source to advance the crystal growth on the seed substrate. When the silicon carbide source and Al are heated and sublimated as in the conventional method for manufacturing an ingot, Al is exhausted at the initial stage of crystal growth due to a difference in vapor pressure between silicon carbide and Al. As a result, distribution of carrier density becomes non-uniform in the growth direction of the ingot. In contrast, in the above-described method for manufacturing the ingot, B is added to reduce the vapor pressure of Al and the silicon carbide source and the mixture are heated at different, appropriate temperatures, thereby advancing the crystal growth while suppressing exhaustion of Al. Therefore, according to the above-described method for manufacturing the ingot, the ingot having uniform distribution of carrier density in the growth direction can be manufactured.

(Appendix 2)

The method for manufacturing the ingot according to Appendix 1, wherein in the step of causing the crystal growth, the silicon carbide source and the mixture are heated respectively in different containers communicating with each other.

In this way, the silicon carbide source and the mixture can be sublimated more readily in appropriate manners.

(Appendix 3)

The method for manufacturing the ingot according to Appendix 2, wherein in the step of causing the crystal growth, the mixture is heated at a temperature higher than that of the silicon carbide source.

In this way, the sublimated silicon carbide source can be suppressed from being deposited on the side where the mixture is disposed.

The ingot, the substrate, and the substrate group in the present invention can be advantageously applied particularly to an ingot, a substrate, and a substrate group, each of which is required to suppress variation of characteristics of semiconductor devices.

Although the present invention has been described and illustrated in detail, it is clearly understood that the same is by way of illustration and example only and is not to be taken by way of limitation, the scope of the present invention being interpreted by the terms of the appended claims.

What is claimed is:

1. An ingot made of single-crystal silicon carbide and containing a p type impurity,
the ingot having a thickness of 10 mm or greater in a growth direction thereof,
the ingot having an average carrier density of 1×10¹⁶ cm⁻³or greater,
the ingot having a carrier density fluctuating in the growth direction by ±80% or smaller relative to said average carrier density.

2. The ingot according to claim 1, wherein the ingot contains aluminum as the p type impurity.

3. The ingot according to claim 1, wherein the ingot is formed through a sublimation method.

4. The ingot according to claim 1, wherein said carrier density monotonously fluctuates in the growth direction.

5. The ingot according to claim 1, wherein said carrier density fluctuates in the growth direction by ±50% or smaller relative to said average carrier density.

6. The ingot according to claim 1, wherein said carrier density fluctuates in the growth direction by ±20% or smaller relative to said average carrier density.

7. A substrate obtained from the ingot recited in claim 1.

8. The substrate according to claim 7, wherein the carrier density fluctuates in a main surface thereof by ±20% or smaller relative to the average carrier density.

9. The substrate according to claim 7, wherein a main surface thereof has an area of 100 cm² or greater.

10. The substrate according to claim 7, wherein the substrate has a warpage of 20 μm or smaller.

11. A substrate group obtained from one ingot,
the substrate group having an average carrier density of 1×10¹⁶cm³ or greater,
variation of carrier density among substrates forming the substrate group being ±80% or smaller relative to the average carrier density of the substrate group.
